(19) United States
(12) Patent Application Publication
(10) Pub. No.: US 2014/0035647 A1
(43) Pub. Date: Feb. 6, 2014

(54) APPARATUS AND METHOD FOR ENHANCING STABILITY OF ELECTRONIC DEVICE HAVING A HIGH-ACCURACY CLOCK

(71) Applicants: CHINA ELECTRIC POWER RESEARCH INSTITUTE, Nanjing (CN); STMICROELECTRONICS (BEIJING) R&D CO., LTD., Beijing (CN)

(72) Inventors: Frank YIN, Beijing (CN); Zongchao MA, Beijing (CN); Minlin CHEN, Beijing (CN)

(21) Appl. No.: 13/933,622

(22) Filed: Jul. 2, 2013

(30) Foreign Application Priority Data
Jul. 2, 2012 (CN) 201210236423.4

(51) Int. Cl. H03K 3/013

(52) U.S. Cl. CPC H03K 3/013
USPC 327/292

(57) ABSTRACT

An embodiment relates to an apparatus and method for enhancing stability of electronic device having a high-accuracy clock. Specifically, there is disclosed a controller for an electronic device, including a control core configured to generate a signal for controlling operation of the electronic device, an internal clock source coupled to the control core and configured to provide a high-speed internal (HSI) clock signal to the control core to act as a drive signal, and at least one timing-sensitive component coupled to an external clock source of the controller and configured to receive a high-speed external (HSE) clock signal generated by an external clock source to act as a drive signal. There is further disclosed a method for driving such kind of controller. According to an embodiment, the high-clock-accuracy requirement and the stability and robustness requirement can be satisfied simultaneously.

### PRIORITY CLAIM

The instant application claims priority to Chinese Patent Application No. 201210236423.4, filed Jul. 2, 2012, which application is incorporated herein by reference in its entirety.

### TECHNICAL FIELD

An embodiment generally relates to the field of electronic device controllers, and more specifically, to an apparatus and method for enhancing stability of electronic devices having a high-accuracy clock.

### SUMMARY

Stability and robustness are important for electronic devices. There is a process for measuring the stability of an electronic device or system. For example, an Electro-Magnetic Compatibility (EMC) test process is leveraged to measure the capability of an electronic device or system in running in its electro-magnetic environment compliantly without generating any unbearable electro-magnetic interference with any device in its environment. Generally speaking, the EMC test has demands in two aspects. In one aspect, the electro-magnetic interference generated by the electronic system during its normal running process should not exceed a certain limit. In the other aspect, the electro-magnetic interference of the electronic system to the environment should have a certain degree of noise immunity, i.e., electro-magnetic insensitivity. For another example, an Electro-Static Discharge (ESD) test process may be leveraged to measure the stability of the electronic device in terms of electrostatic discharge and electrostatic protection.

In practice, out of considerations such as cost control, many electronic devices or systems adopt low-cost microcontroller units (MCU), for example, a microcontroller without a phase-locked loop. Such an MCU generally employs a high-speed external clock separate from the MCU (for example, an external high-accuracy quartz crystal) to drive a MCU core. The external clock can provide relatively high clock accuracy, but might deteriorate the overall stability or robustness of the host device. As a result, it is often difficult or even impossible for the device to pass the EMC test or ESD test.

For example, in the EMC test, an Electrical Fast Transient/Burst (EFT/B) test is an important item for testing the immunity of the electronic device with respect to various transient noises during a handover transient process. Many countries or regions formulate quantitative criteria about EFT/B. For example, according to Chinese state criteria, for a single-phase power meter device, a ±4 KV EFT/B test must be passed. It is already found that an electronic device adopting a high-speed external clock signal to drive the MCU core would rarely pass the EFT/B test.

In contrast, if the MCU core is driven by an internal clock source of the MCU (for example, the clock signal generated by the internal oscillator of the MCU), then the stability of the whole device may be improved, such that it would be relatively easy to pass tests like the EMC test and the ESD test, which measure the stability of an electronic device. However, the internal clock of the MCU generally cannot meet the requirements of clock accuracy. It is understood that in a digital device or a system containing an MCU, there are typically components requiring high clock accuracy, which may be referred as time-sensitive components. For example, a calibration source of a real-time clock (RTC) should have an accuracy of ±5 ppm over −40° C.˜85° C. For another example, components such as timers and counters for accurate timing within the MCU also need clock accuracy higher than other components.

In this way, the MCU in existing electronic devices falls into a dilemma. On one hand, although the requirement of high clock accuracy can be satisfied by employing a high-speed clock signal external to the MCU to drive the MCU core and time-sensitive components, the high stability/robustness of the device typically cannot be guaranteed. On the other hand, although the stability/robustness of the device can be enhanced such that it can easily pass test processes such as EMC test and ESD test by employing a high-speed clock signal within the MCU to drive the MCU core and time-sensitive components, the requirement of high clock accuracy often cannot be satisfied.

Therefore, there is a need for an apparatus and method for enhancing stability of an electronic device having a high-accuracy clock, which can simultaneously satisfy the stability requirement and the high clock accuracy requirement of a device, thereby overcoming the above drawbacks.

In view of the foregoing, embodiments are an apparatus and a method for enhancing stability of an electronic device having a high-accuracy clock.

An embodiment is a controller for an electronic device. The controller includes a control core, an internal clock source, and at least one time-sensitive component. The control core is coupled to the internal clock source and configured to be driven by a high-speed internal (HSI) clock signal generated by the internal clock source. The at least one time-sensitive component is coupled to an external clock source separate from the controller and configured to be driven by a high-speed external (HSE) clock signal generated from the external clock source.

Another embodiment is a method of driving a controller of an electronic device, the controller including a control core and at least one time-sensitive component. The method includes driving the control core with a high-speed internal (HSI) clock signal generated by an internal clock source of the controller, and driving the at least one time-sensitive component with a high-speed external (HSE) clock signal generated by an external clock source separate from the controller.

### BRIEF DESCRIPTION OF THE DRAWINGS

Through reading the following detailed description with reference to the accompanying drawings, features and advantages of one or more embodiments will become more comprehensible. In the drawings, several embodiments are illustrated in an exemplary and non-limiting manner.

FIGS. 1A and 1B show schematic structural block diagrams of electronic device controllers 100A and 100B.

FIG. 2 shows a schematic block diagram of a controller 200 for an electronic device according to an embodiment.

FIG. 3 shows a schematic block diagram of a controller 300 for an electronic device according to another embodiment.

FIG. 4 shows a schematic block diagram of a controller 400 for an electronic device according to still another embodiment.

FIG. 5 shows a schematic block diagram of a controller 500 for an electronic device according to yet another embodiment.

FIG. 6 shows a schematic block diagram of a controller 600 for an electronic device according to another embodiment.

FIG. 7 shows a schematic flowchart of a method 700 for driving a controller of an electronic device according to an embodiment.

In the drawings, the same or corresponding reference numerals may refer to the same or corresponding parts in multiple figures.

### DETAILED DESCRIPTION

Hereinafter, the principle and spirit of the present disclosure will be described with reference to various exemplary embodiments illustrated in the drawings. It should be understood that provision of these embodiments is only to enable those skilled in the art to better understand and further implement the concepts disclosed herein, and is not intended for limiting the scope of the present disclosure in any manner.

A general idea of respective embodiments is that instead of uniformly driving the control core and the time-sensitive component with a high-speed external (HSE) clock signal or a high-speed internal (HSI) clock signal of the controller, the control core and the timing-sensitive component may be individually driven by separate clock signals. Specifically, an embodiment, the MCU core may be driven by the high-speed internal clock signal generated by the internal clock source (for example, an RC oscillator) within the MCU, while the timing-sensitive component is driven by a high-speed external clock signal generated by an external clock source separate from the MCU. In this way, the timing-sensitive component's requirement of clock accuracy can be satisfied, and the electronic devices may have high stability and robustness (thereby relatively easily passing test processes such as EMC test and ESD test).

For the sake of illustration and example, a microcontroller unit (MCU) may be referenced as an example of an electronic device controller in the detailed depiction infra. However, it is only exemplary without any limitation. Any currently known or future developed controller for controlling operation of the electronic device may be used in combination with an embodiment, including, but not limited to, a microcontroller, a universal processor, a private processor, etc.

Besides, the expression “component A is coupled to component B” as used infra means that the component A is connected to component B by means of any appropriate mechanism. The coupled components A and B may communicate with each other or transmit signals with each other. Moreover, the term “couple/coupling” used here may refer to direct coupling (i.e., no further component C exists between component A and component B) or indirect coupling (i.e., A is coupled to another component C, while the component C is in turn coupled to component B).

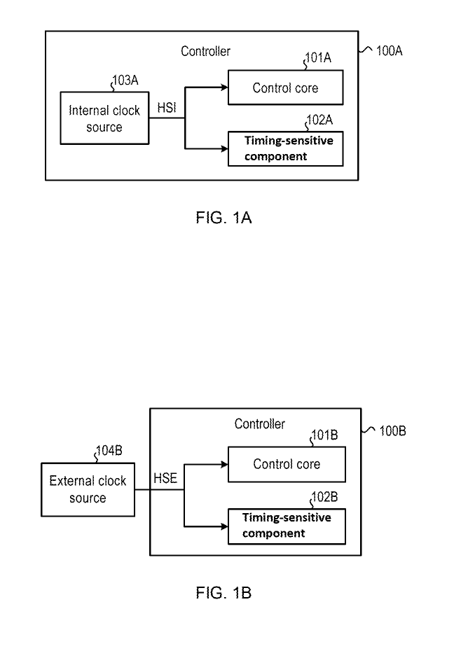

Reference is first made to FIGS. 1A and 1B, which show schematic structural block diagrams of electronic device controllers 100A and 100B. More specifically, in the configuration shown in FIG. 1A, the controller 100A (for example, a MCU) includes a control core 101A (for example, a MCU core) that may be configured to control operations of a host device. Besides, the controller 100A further includes at least one timing-sensitive component 102 that is a component which places a relatively high-demand on clock accuracy in the controller 100A. Examples of the timing-sensitive component 102A include a timer, a counter, etc. As shown in FIG. 1A, both the controller 101A and the timing-sensitive component 102A of the controller 100A are driven by a high-speed internal (HSI) clock signal generated by an internal clock source 103A in the controller 100A. The internal clock source 103A, for example, may be a resistance-capacitance (RC) oscillator, or an oscillator of other types such as a crystal oscillator, or any other appropriate device that can act as the internal clock source. In such a configuration, the controller 100A may relatively easily pass the EMC test (particularly, the EFT/B test) and ESD test, etc. However, since the clock accuracy generated by devices such as the RC oscillator is generally low (for example, the error may be ±1%), it is likely that the clock-accuracy requirement of the timing-sensitive component 102A cannot be satisfied.

Refer to FIG. 1B, which shows a controller 100B of another configuration. The control core 101B and the time-sensitive component 102B in FIG. 1B are similar to the control core 100A and the time-sensitive component 102A in FIG. 1A, respectively. However, in the configuration of FIG. 1B, both the control core 101B and the time-sensitive component 102B are driven by a high-speed external (HSE) clock signal generated by an external clock source 104B separate from the controller 100B. Examples of the external clock source 104B include a crystal, for example, a quartz crystal or a ceramic crystal; or any other device that can generate a high-speed accurate clock. Of course, other components may exist between the external clock source 104B and the control core 101B or the timing-sensitive component 102B. Different from the configuration of FIG. 1A, in the configuration of FIG. 1B, the controller 100B's requirement on high timing accuracy can be well satisfied. However, such a configuration has a drawback that the characteristics of the external clock source 104B may cause that the host device might not pass test processes measuring the stability of the electronic device, such as an EMC test, an ESD test, and the like.

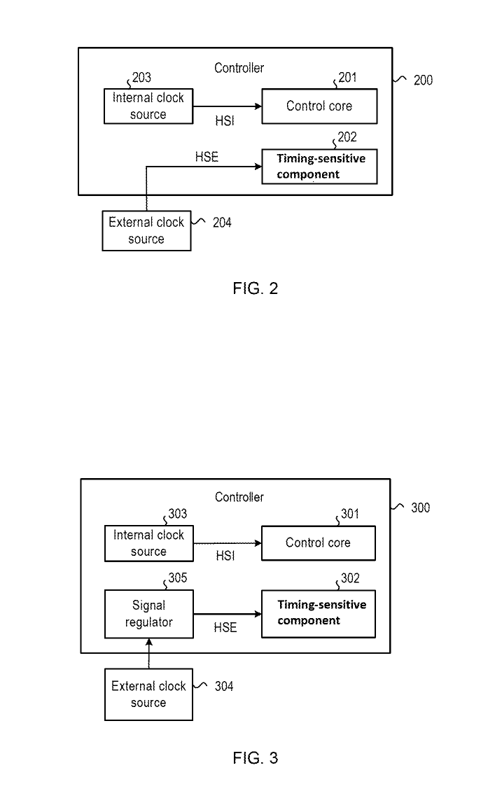

Refer to FIG. 2, which shows a schematic block diagram of a controller 200 for an electronic device according to an embodiment. As shown, according to an embodiment, the controller 200 for an electronic device or system (not shown) includes a control core 201. For example, in the case that the controller 200 is a MCU, the control core 201 may be a MCU core. In the operation, the control core 201 is configured to generate various signals controlling operations of the host electronic device. Additionally, the controller 200 further includes at least one timing-sensitive component 202 (although only one is shown in the figure, the actual number may be random), for example, a timer or counter for accurately timing or counting, etc.

Furthermore, as shown in FIG. 2, according to an embodiment, the controller 200 further includes an internal clock source 203 coupled to the control core 201 and configurable to generate a high-speed internal (HSI) clock signal. For example, in an embodiment, the internal clock source 203 may be an RC oscillator. It is only exemplary and currently known or future developed devices, or any other appropriate device, may be used in combination with an embodiment.

In operation, the internal clock source 203 is configured to generate an appropriate HSI clock signal as required by the controller 200. The control core 201 is configured to receive the HSI clock signal from the internal clock source 203 and is driven by that HSI clock signal. Different from the configurations illustrated in FIGS. 1A and 1B, instead of being driven by the HSI clock signal generated by the internal clock source 203, the timing-sensitive component 202 is coupled to the external clock source 204 separate from the controller 200. In operation, the external clock source 204 is configured to generate an appropriate HSE clock signal as required by the controller 200. In general, the HSE clock signal generated by the external clock source 204 is more accurate than the HSI clock signal generated by the internal clock source 203. The timing-sensitive component 202 in the controller 200 is configured to receive the HSE clock signal generated by the external clock source 204 and is driven by that HSE clock signal.

In addition, the controller 200 further includes at least one non-timing-sensitive component (not shown in FIG. 1). Compared with the timing-sensitive component 202, these non-timing-sensitive components have a relatively low requirement on the clock accuracy. According to an embodiment, one or more of these non-timing-sensitive components may be driven with the HSI clock signal generated by the internal clock source 203.

In the configuration shown in FIG. 2, the control core 201 of the controller 200 is configured to be driven by the HSI clock signal generated by the internal clock source 203. In the meantime, the at least one timing-sensitive component 202 is configured to be driven by a more accurate HSE clock signal generated by the external clock source 204 separate from the controller 200. In this way, the timing-sensitive component 202's higher demand on clock accuracy can be better guaranteed, while the controller 200 and its host device are more likely to have a relatively high stability and robustness as a whole. As such, the electronic device is more likely to be able to successfully pass various test processes of measuring the stability of an electronic device, such as an EMC test, an ESD test, and the like.

FIG. 3 shows a schematic block diagram of a controller 300 for an electronic device according to a further embodiment. The controller 300 as shown in FIG. 3 is an alternative variation of the controller 200 of FIG. 2 as described above. Specifically, a control core 301, a timing-sensitive component 302, an internal clock source 303, and an external clock source 304 included in the controller 303 correspond to the control core 201, the timing-sensitive component 202, the internal clock source 203, and the external clock source 203 as described above with reference to FIG. 2, and their functions and operations will not be detailed here.

The controller 300 differs from the controller 200 in that the external clock source 304 is not directly coupled to the timing-sensitive component 302, but is coupled to the timing-sensitive component 302 via a signal regulator 305 included in the controller 300. In practice, out of the considerations of performance and cost, a quartz crystal or ceramic crystal may be used as the external clock source 304, for example. It is appreciated that the signal generated by such an external clock source 304 is usually not in the form square wave, but in another form such as a sine wave. On the other hand, the timing-sensitive component 302 may be required to be driven by a clock signal of a square wave. To this end, the signal regulator 305 may be configured to regulate the signal received from the external clock source 304 into the form of square wave to thereby generate the final HSE clock signal to be fed to the timing-sensitive component 302. According to an embodiment, for example, an appropriate crystal-oscillator circuit may be adopted to act as the signal regulator 305. Of course, it is only exemplary, and any device having a signal regulation function may be used in combination with an embodiment.

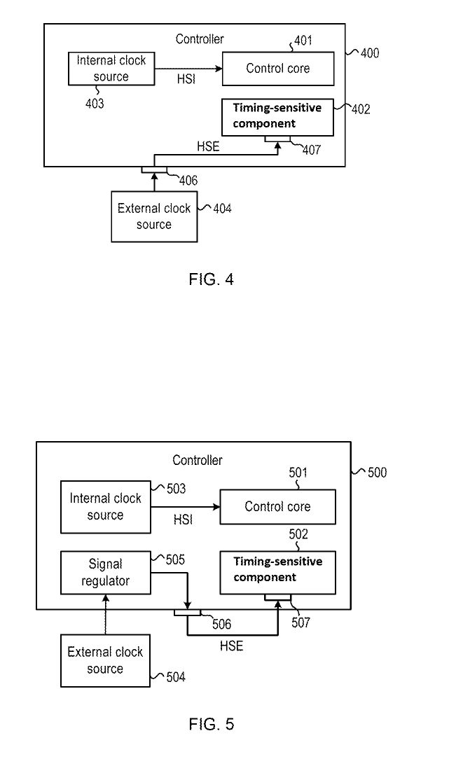

Reference is now made to FIG. 4, which shows a schematic block diagram of a controller 400 for an electronic device according to an embodiment. The controller 400 as shown in FIG. 4 is another alternative variation of the controller 200 as above depicted above in conjunction with FIG. 2. Specifically, a control core 401, a timing-sensitive component 402, an internal clock source 403, and an external clock source 404 correspond to the control core 201, the timing-sensitive component 202, the internal clock source 203, and the external clock source 204 as described with reference to FIG. 2, respectively, and their functions and operations will not be detailed here.

The controller 400 differs from the controller 200 in that the external clock source 404 is not directly coupled to the timing-sensitive component 402, but is coupled to the timing-sensitive component 400 via pins 406 and 407 of the controller 400. The configuration as shown in FIG. 4 mainly intends to adapt embodiments of a controller to those existing controllers where the configurations as described herein cannot be directly implemented.

Specifically, some existing controllers (for example, STM8 S/L, and the like) do not support directly coupling a timing-sensitive component, such as a timer, to an external clock source that generates an HSE clock signal. According to an embodiment, additional pins may be provided on the controller to feed the HSE clock signal from the external clock source to the pins of the timing-sensitive components and further to the timing-sensitive components. In this way, the compatibility of an embodiment with the existing controllers may be improved.

It should be understood that the pins serving as the intermediate coupling mechanism may be of any number depending on specific implementations, not limited to two as shown in FIG. 4. It is also appreciated that although pins 406 and 407 are illustrated within the controller 400 in FIG. 4, it is only a schematic representation. In an actual implementation, the pins may be located, for example, at any appropriate location of the controller 400, for example, an edge or a periphery. Moreover, the coupling between pins may be implemented through peripheral wires of the controller 400.

Specifically, the embodiments as shown in FIGS. 3 and 4 may be used in combination, and such an exemplary embodiment is shown in FIG. 5. In particular, in the embodiment of FIG. 5, the signal generated from an external clock source 504 is fed to a signal regulator 505 in a controller 500, which signal regulator is similar to the signal regulator 305 as described with reference to FIG. 3. The signal regulator 505 regulates the received signal into a form of square wave which will be used as the HSE clock signal. The HSE clock signal is then fed to a first pin 506 of the controller 500. The first pin 506 in turn feeds the HSE clock signal to a second pin 507 through a peripheral wire of the controller 500 so as to drive a timing-sensitive component 502.

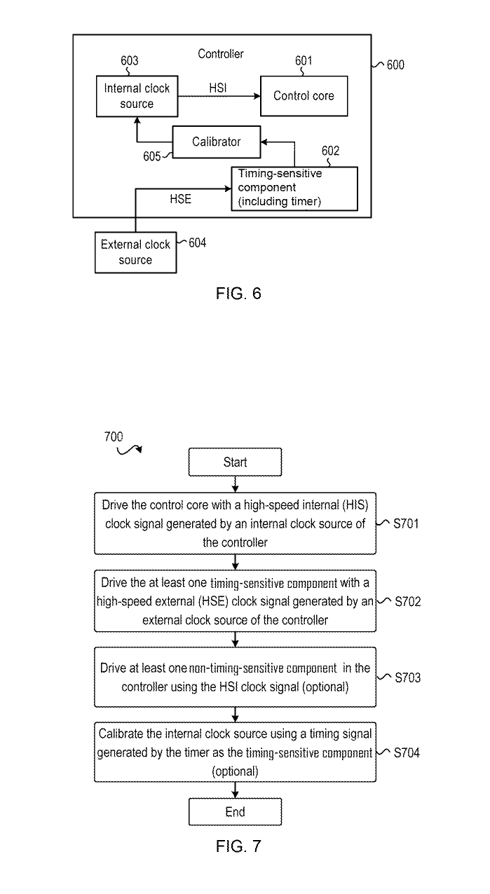

Now refer to FIG. 6, which shows a schematic block diagram of a controller 600 for an electronic device according to a further embodiment. The controller 600 as shown and depicted in FIG. 6 is another alternative variation of the controller 200 as described above. Specifically, a control core 601, a timing-sensitive component 602, an internal clock source 603, and an external clock source 604 included in the controller 600 correspond to the control core 201, the timing-sensitive component 202, the internal clock source 203, and the external clock source 204 as described with reference to FIG. 2, and their functions and operations will not be detailed here.

In the example shown in FIG. 6, the timing-sensitive component 602 includes a timer (of course, it may further include any other timing-sensitive components) for purposes of high-accuracy timing. In operation, the timer may generate a high-accuracy timing signal. The controller 600 mainly differs from the controller 200 in that the controller 600 further includes a calibrator 605, which is coupled between the internal clock source 603 and the timer 602 as a timing-sensitive component and which is configured to calibrate the internal clock source 603 with the high-accuracy timing signal generated by the timer 602. The accuracy of the HSI clock signal may be significantly improved by calibrating the internal oscillator (for example, an RC oscillator) with the high-accuracy timing signal generated by the timer driven by the HSE clock signal. It has been proven that such processed HSI clock accuracy is good enough for many application purposes.

It is understood that the embodiments depicted above with reference to FIGS. 2 to 6 are not mutually exclusive to each other. On the contrary, any two or more embodiments in these examples may be combined freely to implement another embodiment. The controller implemented as such likewise falls within the scope of the present disclosure.

It is further understood that the controller as described above with reference to FIGS. 2 to 6 may be implemented in various ways. For example, in some embodiments, the controller may be implemented as an integrated circuit (IC) chip or an application-specific integrated circuit (ASIC) chip. The controller may also be implemented as a system-on-chip (SOC), a field-programmable gate array (FPGA), and etc. In particular, various components included in the controller may be integrated onto a single chip or onto separated different chips, and the scope of the present disclosure is not limited in this aspect. Actually, other currently known or future developed ways of implementation are all feasible.

Next refer to FIG. 7, which shows a schematic flow chart of a method 700 for driving a controller of an electronic device according to an embodiment. The electronic device includes a control core and at least one timing-sensitive component.

As described in FIG. 7, after the method 700 starts, at step S701, the control core of the controller is driven by a high-speed internal (HSI) clock signal generated by an internal clock source (for example, any internal clock source as described above with reference to FIGS. 2-6) of the controller (for example, any controller as described above with reference to FIGS. 2-6). According to an embodiment, a RC oscillator, for example, may be used as the internal clock source.

Next, at step S702, at least one timing-sensitive component (for example, any timing-sensitive component as described above with reference to FIGS. 2-6) of the controller may be driven by a high-speed external (HSE) clock signal generated by an external clock source (for example, any external clock source as described above with reference to FIGS. 2-6) separate from the controller.

According to an embodiment, a crystal (for example, a quartz crystal, a ceramic crystal, etc.) may be used as the external clock source. At this point, according to an embodiment, the controller may have inside one or more signal regulators (for example, signal regulators 305 and 505 as described above with reference to FIGS. 3 and 5). The signal regulator, for example, may be a crystal oscillator or a crystal-oscillator circuit. In such an embodiment, at step S702, the signal generated by the external clock source may be regulated to be a form of square wave by using a signal regulator. The regulated square wave signal is then fed to the timing-sensitive component as an HSE clock signal.

Additionally, according to an embodiment, the HSE clock signal generated by the external clock source may be fed to the timing-sensitive component via the pins of the controller (for example, the pins depicted above with reference to FIGS. 4 and 5). In this way, an embodiment is applicable to those controllers that do not support directly coupling the timing-sensitive component to the external clock source, thereby improving the compatibility to existing devices.

Next, the method 700 may proceed to optional step S703 to drive the at least one non-timing-sensitive component in the controller, i.e., those components having a relatively lower clock-accuracy requirement, with the HSI clock signal.

In an embodiment where the timing-sensitive component in the controller includes a timer, the method 700 may then proceed to an optional step S704 to calibrate the internal clock source with the high-accuracy timing signal generated by the timer. In this way, the accuracy of the HSI clock signal generated by the internal clock source may be improved.

The method 700 ends after step S704.

It is understood that the steps illustrated in method 700 are only schematic. For example, these steps may be executed in different sequences or even executed in parallel. Besides, the method 700 may include additional steps, substitute some steps, or even omit some steps.

The spirit and principle of the present disclosure has been illustrated above with reference to a plurality of embodiments. Different from uniformly driving both the control core and the timing-sensitive component by an HSE clock source or an HSI clock source of the controller, an embodiment allow separately driving the control core and the timing-sensitive component by individual clock signals. Specifically, in an embodiment, the control core may be driven by a high-speed internal clock generated by an internal clock source in the controller, and meanwhile, the timing-sensitive component may be driven by a high-speed external clock generated by an external clock source separate from the controller. In this way, the high clock accuracy requirement of the electronic device can be satisfied, and meanwhile the electronic device or system would have a higher stability and robustness as a whole.

The devices and modules thereon as involved in the present disclosure may be implemented by hardware, for example, a very large scale integration or gate array, a semiconductor such as logic chip, transistor, etc., or a hardware circuit of a programmable hardware device such as a field-programmable gate array, a programmable logic device, etc. Alternative or additionally, an embodiment may also be implemented by software, firmware, or a combination of subcombination of hardware, software, and firmware.

It is noted that although a plurality of means or sub-means of the device have been mentioned in the above detailed depiction, such partitioning is merely non-compulsory. In actuality, according to an embodiment, the features and functions of the above-described two or more means may be embodied in one means. In turn, the features and functions of the above described one means may be further embodied in more modules.

It should be also noted that the connection lines between respective blocks as illustrated in the structural block diagrams merely indicate the coupling relationship between the components or the information transmission direction between the components, not necessarily representative of the actual connections between components. On the contrary, according to the actual implementation means, the coupling between components may be implemented through various appropriate manners. The scope of the present disclosure is not limited thereto.

Besides, although operations of the present methods are described in a particular order in the drawings, it does not require or imply that these operations must be performed according to this particular sequence, or a desired outcome can only be achieved by performing all shown operations. On the contrary, the execution order for the steps as described in the flowcharts may be varied. Additionally or alternatively, some steps may be omitted or added, a plurality of steps may be merged into one step, or a step may be divided into a plurality of steps for execution.

Although the present disclosure includes reference to a plurality of embodiments, it should be understood that the disclosure is not limited to the disclosed embodiments. On the contrary, an embodiment intends to cover various modifications and equivalent arrangements. For example, one or more of the controllers 200-00 of FIGS. 2-6 may be other computing circuits such as microprocessors.

From the foregoing it will be appreciated that, although specific embodiments have been described herein for purposes of illustration, various modifications may be made without deviating from the spirit and scope of the disclosure. Furthermore, where an alternative is disclosed for a particular embodiment, this alternative may also apply to other embodiments even if not specifically stated.

1.-14. (canceled)

15. An integrated circuit, comprising:
a generator configured to generate a first clock signal;
a first circuit coupled to the generator;
a first node configured to receive a second clock signal; and
a second circuit coupled to the first node,

16. The integrated circuit of claim 15 wherein the generator is configured to generate the first clock signal such that the first clock signal has a lower accuracy than the second clock signal.

17. The integrated circuit of claim 15 wherein the first circuit includes a control core.

18. The integrated circuit of claim 15 wherein the first node includes an input pin.

19. The integrated circuit of claim 15 wherein the second circuit includes a timing-sensitive circuit.

20. The integrated circuit of claim 15 wherein the second circuit includes a clock-timing-sensitive circuit.

21. The integrated circuit of claim 15, further comprising a modifier disposed between the first node and the second circuit and configured:
generate, from the second clock signal having a first shape, a third clock signal having a second shape; and
to provide the third clock signal to the second circuit.

22. The integrated circuit of claim 15, further comprising a modifier disposed between the first node and the second circuit and configured:
to generate, from the second clock signal, a square wave; and
to provide the square wave to the second circuit.

23. The integrated circuit of claim 15, further comprising a modifier disposed between the first node and the second circuit and configured:
to generate, from the second clock signal, a third clock signal having edges; and
to provide the third clock signal to the second circuit.

24. The integrated circuit of claim 15, further comprising:
a second node;
a third node coupled to the second node and to the second circuit;
a modifier disposed between the first node and the second node and configured
to generate, from the second clock signal having a first shape, a third clock signal having a second shape; and
to provide the third clock signal to the second node.

25. The integrated circuit of claim 15, further comprising:
wherein the second circuit is configured to generate a timing signal in response to the second clock signal; and
a calibrator configured to calibrate the generator in response to the timing signal.

26. A system, comprising:
a first integrated circuit, including
a generator configured to generate a first clock signal,
a first circuit coupled to the generator;
a first node configured to receive a second clock signal; and
a second circuit coupled to the first node; and
a second integrated circuit coupled to the first integrated circuit and configured to generate the second clock signal,

27. The system of claim 26 wherein the first integrated circuit includes a computing circuit.

28. The system of claim 26 wherein the second integrated circuit includes a crystal.

29. The system of claim 26 wherein the second integrated circuit includes a crystal oscillator circuit.

30. The system of claim 26 wherein the first and second integrated circuits are disposed on a same die.

31. The system of claim 26 wherein the first and second integrated circuits are disposed on respective dies.

32. A method, comprising:
generating a first clock signal on an integrated circuit;
clocking with the first clock signal a first circuit that is disposed on the integrated circuit; and
clocking with a second clock signal from a source that is external to the integrated circuit a second circuit that is disposed on the integrated circuit.

33. The method of claim 32 wherein the second clock signal is more accurate than the first clock signal.

34. The method of claim 32 wherein the first circuit includes a core of a computing circuit.

35. The method of claim 32 wherein the second circuit includes a timing-sensitive circuit.

36. The method of claim 32 wherein clocking the second circuit includes:
generating on the integrated circuit from the second clock signal a third clock signal having a different shape than the second clock signal; and
clocking the second circuit with the third clock signal

37. The method of claim 32 wherein clocking the second circuit includes:
generating on the integrated circuit from the second clock signal a third clock signal having edges; and
clocking the second circuit with the third clock signal

38. The method of claim 32, further comprising calibrating the generating of the first clock signal in response to the second clock signal.
